(19) United States
(12) Patent Application Publication
(10) Pub. No.: US 2025/0336679 A1
(43) Pub. Date: Oct. 30, 2025

(54) METHOD FOR MANUFACTURING SIC POWER SEMICONDUCTOR DEVICE USING HOT SELF-SPLIT PROCESS

(71) Applicant: WAVELORD CO, LTD., Gyeonggi-do (KR)

(72) Inventor: June O SONG, Gyeonggi-do (KR)

(21) Appl. No.: 19/188,176

(22) Filed: Apr. 24, 2025

(30) Foreign Application Priority Data
Apr. 24, 2024 (KR) 10-2024-0055060
Jul. 23, 2024 (KR) 10-2024-0096854

(51) Int. Cl. H01L 21/285; H01L 21/324; H01L 21/683; H10D 8/01; H10D 30/01

(52) U.S. Cl. CPC H01L 21/28537; H01L 21/324; H01L 21/6835; H10D 8/045; H10D 8/051; H10D 30/0297; H01L 2221/68381

(57) ABSTRACT

Embodiments according to the present invention comprise a step of preparing a SiC seed substrate having conductivity; a device region forming step; a first fab process step including a doping process for a SiC power semiconductor device and an electrode forming process in the device region; a seed substrate reforming step; an upper temporary substrate bonding step; and a seed region separation step of separating the SiC seed substrate with the reforming layer as a boundary to form a seed region; and wherein the seed region separation step is performed in a process of cooling from a bonding temperature for bonding the upper temporary substrate, and separation is performed without an external force by thermal/mechanical stress due to a difference in thermal expansion rate and thickness on both sides of the reforming layer as a boundary.

### CROSS-REFERENCE TO RELATED APPLICATIONS

This application claims priority to Korean Patent Application Nos. 10-2024-0055060, filed on Apr. 24, 2024 and 10-2024-0096854, filed on Jul. 23, 2024. The entire disclosure of the applications identified in this paragraph is incorporated herein by reference.

### FIELD

The present invention relates to a method for manufacturing a SiC power semiconductor device using a hot self-split process, and more particularly, to a method for manufacturing a SiC power semiconductor device capable of achieving cost innovation while using an expensive SiC wafer as a seed substrate for growing SiC device region.

### BACKGROUND

Power semiconductors are one of the semiconductor devices essential for smoothly supplying electrical energy used in all areas of human life and industry.

Due to climate change, the demand for heating and cooling energy is skyrocketing, and recently, industrial systems that consume massive amounts of energy, such as AI (Artificial Intelligent), are developing more and more.

Therefore, high quality and high performance of power semiconductors are required to enable stable operation even in high voltage, high current, and high temperature environments.

SiC power semiconductors are manufactured with the most suitable material for high voltage, high output, and high efficiency switching power devices, and are attracting attention as a future semiconductor material that will replace silicon (Si) power semiconductors.

If SiC power semiconductors are installed in electric vehicles, they can be expected to improve energy efficiency by up to 10% by reducing battery power consumption and reducing the weight and volume of the vehicle body.

However, despite the above-mentioned advantages, the market expansion of SiC power semiconductors is difficult due to high cost issues.

As one way to solve this problem, the development of a method that can use SiC growth substrates in a cost-effective manner in the process of manufacturing SiC power semiconductors is required.

### SUMMARY

### Technical Problem

The present invention provides a method for manufacturing a SiC power semiconductor device, which can solve the high cost issue of a SiC growth substrate through a hot self-split process while applying a SiC growth substrate for a high-quality and high-performance SiC power semiconductor.

The present invention provides a method for manufacturing a SiC power semiconductor device, which can drastically reduce the manufacturing cost of a SiC power semiconductor device, since a SiC growth substrate separated by a hot self-split process can be reused as a growth substrate for SiC device region.

The present invention provides a method for manufacturing a SiC power semiconductor device, which can separate a thin SiC seed region from a thick SiC growth substrate without external force using a stealth laser and a wafer bonding process.

### Technical Solution

Embodiments according to the present invention provide a method for manufacturing a SiC power semiconductor device through a hot self-split process, comprising: a seed substrate preparation step of preparing a SiC seed substrate having conductivity; a device region forming step of forming a device region including a SiC drift layer epitaxially grown on the SiC seed substrate; a first fab process step including a doping process and an electrode forming process for forming one of a planar MOSFET, a trench MOSFET, a Schottky diode, and a trench P-N junction diode in the device region; a seed substrate reforming step of irradiating a stealth laser into the inside of the SiC seed substrate to form a reforming layer parallel to a growth plane of the SiC seed substrate over the entire inside of the SiC seed substrate; an upper temporary substrate bonding step of bonding an upper temporary substrate to an upper surface of the device region via an upper bonding layer; a seed region separation step of separating the SiC seed substrate with the reforming layer as a boundary to form a seed region; a second fab process step of forming an electrode on a lower surface of the seed region; and a lower temporary substrate bonding step of bonding a lower temporary substrate to the lower surface of the seed region via a lower bonding layer; and, wherein the seed region separation step is performed without an external force by thermal/mechanical stress due to a difference in thermal expansion rate and thickness on both sides of the reforming layer as a boundary.

In embodiments according to the present invention, the seed region separation step is performed in a process of cooling from a bonding temperature for bonding the upper temporary substrate.

Embodiments according to the present invention further comprise an upper temporary substrate removal step of removing the upper temporary substrate after performing the lower temporary substrate bonding step; and a lower temporary substrate removal step of removing the lower temporary substrate after removing the upper temporary substrate.

In embodiments according to the present invention, the first fab process step is performed while removing the upper temporary substrate and maintaining bonding of the lower temporary substrate, and the second fab process step is performed after removing the lower temporary substrate.

In embodiments according to the present invention, the first fab process step comprises a doping step of forming a doping region (Ion Implantation Doping Region) for a source contact on an upper side of the device region; and an upper electrode formation step of forming a gate electrode and a source electrode on an upper surface of the device region; thereby forming the Planar MOSFET in the device region.

In embodiments according to the present invention, the first fab process step comprises a doping step of forming a doping region (Ion Implantation Doping Region) for a source contact (Source Contact) on an upper side of the device region; a gate trench forming step of forming a trench (Trench) in which a gate electrode is to be formed; and an upper electrode forming step of forming a Gate Electrode and a source electrode (Source Contact) on an upper surface of the device region, thereby forming the trench MOSFET in the device region.

In embodiments according to the present invention, the first fab process step comprises an upper electrode forming step of forming an anode electrode formed as a Schottky contact on an upper surface of the device region, thereby forming the Schottky diode in the device region.

In embodiments according to the present invention, the first fab process step comprises a trench forming step of forming a plurality of trenches on an upper surface of the device region; a P-doping step of performing P-doping on the inside of the trenches; and an upper electrode forming step of forming an anode electrode formed as a Schottkey contact on the upper surface of the device region and the inner surface of the trenches, thereby forming the trench P-N junction diode in the device region.

In embodiments according to the present invention, the second fab process step deposits a drain electrode to form the Planar MOSFET or the Trench MOSFET, or deposits a metal electrode to form the Schottky diode or the Trench P-N Junction diode, and after bonding the lower temporary substrate, heat treatment is performed for ohmic contact of the drain electrode or the metal electrode.

In embodiments according to the present invention, the SiC seed substrate is repeatedly provided as a SiC seed substrate for the growth of the SiC drift layer after the seed region is separated.

### Advantageous Effects

According to the present invention, since the SiC seed region can be separated thinly by the hot self-split process, a thick SiC growth substrate can be used for the epitaxial growth of the SiC device region.

Accordingly, the quality uniformity of the SiC device region is improved.

In addition, since the warpage of the SiC growth substrate is prevented, defects such as wafer cracks are prevented.

According to the present invention, in the process of manufacturing a SiC power semiconductor device, the SiC seed substrate is separated into seed regions so that it can be reused, thereby drastically reducing the manufacturing cost.

### BRIEF DESCRIPTION OF DRAWINGS

FIG. 1 is a drawing showing a first embodiment of a method for manufacturing a SiC power semiconductor device through a hot self-split process according to the present invention.

FIG. 2 is a drawing showing a second embodiment of a method for manufacturing a SiC power semiconductor device through a hot self-split process according to the present invention.

FIG. 3 and FIG. 4 are drawings explaining a first fab process step and a second fab process step in a method for manufacturing a SiC power semiconductor device through a hot self-split process according to the present invention.

### DETAILED DESCRIPTION

Hereinafter, Hereinafter, a method for manufacturing a SiC power semiconductor device according to embodiments of the present invention will be described in detail with reference to the drawings.

The terms used below have been selected for convenience of explanation, and should be appropriately interpreted in a meaning that is consistent with the technical idea of the present invention without being limited to the dictionary meaning.

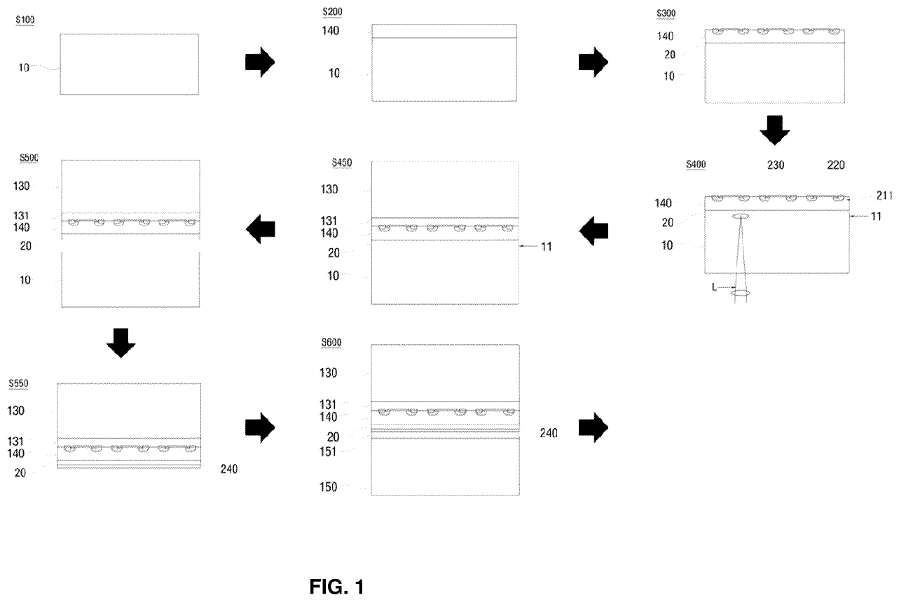

Referring to FIG. 1, the present embodiment comprises a seed substrate preparation step (S100), device region forming step (S200), a first fab process step (S300), a seed substrate reforming step (S400), an upper temporary substrate bonding step (S450), a seed region separation step (S500), a second fab process step (S550) and a lower temporary substrate bonding step (S600).

In the SiC seed substrate preparation step (S100), a SiC seed substrate (10) having conductivity is prepared.

The SiC seed substrate (10) has a thickness of 300 μm or more, and considering the purpose of the present invention, it is preferable to have a maximum thickness that allows the MOCVD process.

In the device region forming step (S200), a device region (140) including a SiC drift layer epitaxially grown on the SiC seed substrate (10) is formed.

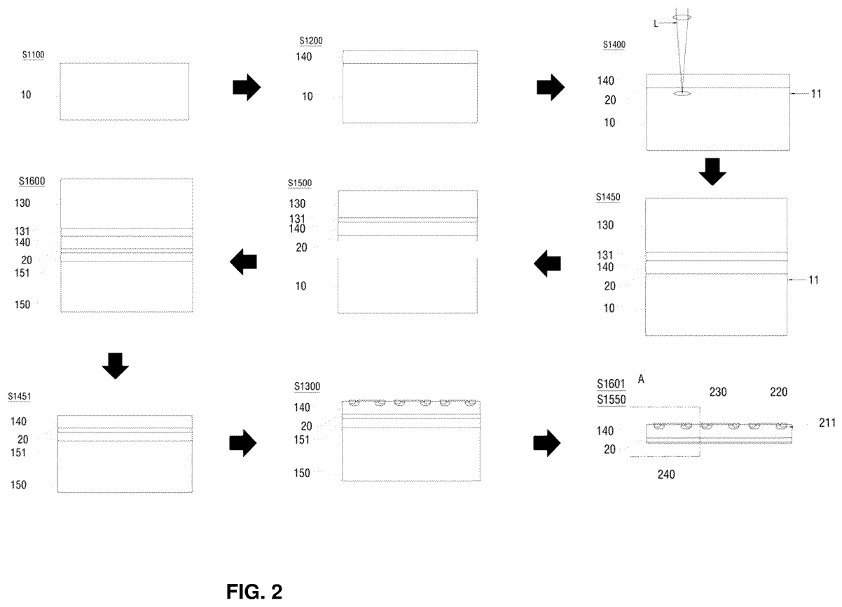

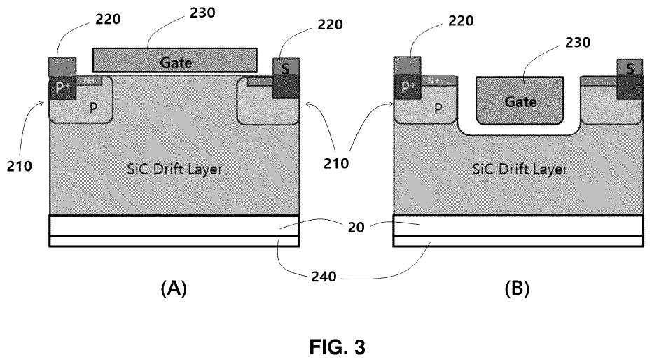

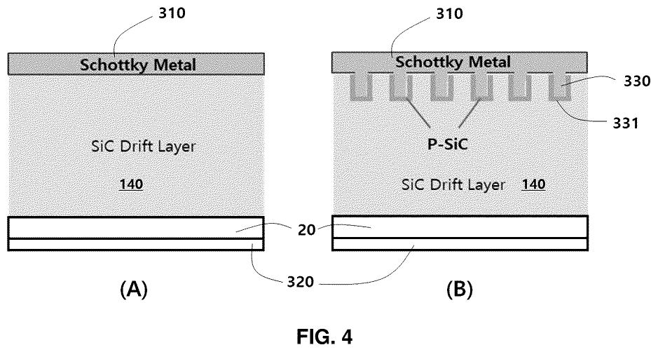

The first fab process step (S300) includes a doping process and an electrode forming process for forming one of a planar MOSFET ((A) of FIG. 2), a trench MOSFET ((B) of FIG. 3), a Schottky diode ((A) of FIG. 4), and a trench P-N junction diode ((B) of FIG. 4) on the device region (140).

The first fab process step (S300) forms some of the components that form a SiC power semiconductor device in the device region (140).

Some of the components forming a SiC power semiconductor device are the gate electrode and source electrode of a MOSFET (Metal Oxide Semiconductor Field Effect Transistor), and a heavily doped region for the ohmic contact of the source electrode. The heavily doped region is formed using an ion implantation process.

Meanwhile, if the SiC power semiconductor device is a Schottky diode, a Schottky electrode is formed, and if it is a trench P-N junction diode, a trench-structured Schottky electrode is formed.

The SiC seed substrate reforming step (S400) irradiates a stealth laser to the SiC seed substrate (10) through the lower surface of the SiC seed substrate (10) to form a reforming layer (11) inside the SiC seed substrate (10).

The reforming layer (11) is formed over the entire inside of the SiC seed substrate (10) parallel to the growth plane of the SiC seed substrate (10).

The stealth laser (L) is a laser with a wavelength that can penetrate the SiC seed substrate (10) and forms a focal point at a specific point inside the SiC seed substrate (10).

Therefore, when the focal point of the stealth laser (L) moves along a specific plane and forms a scanning plane in the shape of a point, line, or lattice cell, a reforming layer (11) is formed along the scanning plane.

In this embodiment, it is preferable that the stealth laser (L) is irradiated from the lower surface of the SiC seed substrate (10), but it is not excluded that it is irradiated from the upper surface of the device region (140).

The upper temporary substrate bonding step (S450) bonds the upper surface of the device region (140) and the upper temporary substrate (130) via the upper bonding layer (131).

The bonding of the upper temporary substrate (130) is for stable workability of the post-process.

The upper temporary substrate (130) can be made of sapphire, silicon, SiC, or AlN.

The upper bonding layer (131) is made of ceramic inorganic materials such as SiO₂, SOG, SiNₓ, or AlN.

Bonding is performed at a temperature of 100 to 350° C. depending on the bonding material.

The seed region separation step (S500) is separated without external force during the cooling process at the bonding temperature of the upper temporary substrate bonding step (S450).

The upper temporary substrate bonding step (S450) provides stable workability, thereby reducing the manufacturing cost of SiC power semiconductor devices and contributing to improved yield.

Since the upper temporary substrate (130) is bonded after the device region (140) is formed on the SiC seed substrate (10), and the seed region (20) is separated by the reforming layer (11), the possibility of damage to the device region (140) can be reduced.

In addition, the upper temporary substrate (130) provides structural stability for performing subsequent processes such as polishing and CMP on the lower surface of the separated seed region (20).

Ultimately, the upper temporary substrate (130) not only safely protects the device region (140), but also minimizes the thickness of the seed region (20), thereby reducing manufacturing costs.

In addition, the upper temporary substrate (130) maximizes the structural asymmetry on both sides with the reforming layer (11) as a boundary, thereby smoothly performing the hot self-split process.

The seed region separation step (S500) separates the SiC seed substrate (10) on the device region (140) side with the reforming layer (11) as the boundary to form the seed region (20).

The seed region separation step (S500) generates thermal stress or mechanical stress in the reforming layer (11) by having a structural asymmetry including a quantitative difference in thermal characteristics including a thermal expansion coefficient or a thickness difference between the two sides with the reforming layer (11) as the boundary.

Therefore, the SiC seed substrate (10) is separated without a mechanical external force with the reforming layer (11) as the boundary.

That is, due to the bonding temperature of the upper temporary substrate bonding step (S450), the two sides with the reforming layer (11) as the boundary have a difference in thermal expansion coefficient, and this difference becomes more evident due to the structural asymmetry. Afterwards, the separation is performed without an external force during the cooling process.

More specifically, one side is a structure in which a seed region (20), a device region (140), and an upper temporary substrate (130) are laminated with the reforming layer (11) as the boundary, and the other side is a seed substrate (10) having a thickness excluding the thickness of the seed region (20).

Therefore, due to the structural difference, the effective thermal expansion coefficient and effective thermal conductivity of both sides with the reforming layer (11) as the boundary are different from each other.

This is the reason why the two sides with the reforming layer (11) as the boundary have different thermal expansion coefficients, and it acts as a factor in separation without external force with the reforming layer (11) as the boundary.

In addition, the two sides with the reforming layer (11) as the boundary have different thicknesses and materials. Therefore, the internal stress distribution of the two sides with the reforming layer (11) as the boundary is different.

This creates mechanical stress at the boundary of the reforming layer (11) and acts as another factor that separates the two without external force centered on the reforming layer (11).

Meanwhile, the SiC seed substrate (10) from which the seed region (20) is separated by the seed region separation step (S500) is provided as a growth substrate for the growth of a new device region (140).

In addition, this process is repeated. As a result, the manufacturing cost of the SiC power semiconductor device can be drastically reduced.

In other words, the cost-effectiveness of the expensive SiC seed substrate is improved.

The second fab process step (S550) forms an electrode on the lower side of the seed region (20). This completes the configuration for forming a SiC power semiconductor device.

It is preferable that a surface planarization process (mechanical polishing, CMP) is performed on the lower side of the seed region (20) before the second fab process step (S550).

If the SiC power semiconductor device is a MOSFET, the second fab process step (S550) includes a process for forming a drain ohmic contact and an electrode (240, see FIG. 3) on the lower side of the seed region (20).

When the SiC power semiconductor device is a diode, the second fab process step (S550) includes a process of forming a cathode electrode (320, see FIG. 4) formed as an ohmic contact on the lower side of the seed region (20).

The lower temporary substrate bonding step (S600) is a step of bonding the lower temporary substrate (150) to the lower surface of the seed region (20) via the lower bonding layer (151). To be precise, the lower temporary substrate (150) is bonded to the electrode formed by the second fab process step (S550).

The lower temporary substrate (150) may be made of sapphire, silicon, SiC, or AlN.

In addition, the lower bonding layer (151) is made of a ceramic inorganic material such as SiO₂, SOG, SiNₓ, or AlN.

In the present embodiment, prior to bonding the upper temporary substrate (130) and the lower temporary substrate (150), a passivation layer may be formed on the device region (140) and the electrode.

Meanwhile, in the present embodiment, the upper temporary substrate (130) and the lower temporary substrate (150) are sequentially removed (S451, S601), and a thin SiC power semiconductor device is manufactured.

The lower temporary substrate (150) minimizes adverse effects on the seed region (20) and the SiC power semiconductor device when the upper temporary substrate (130) is removed.

In addition, the lower temporary substrate (150) provides structural stability when performing processes such as passivation and heat treatment of the SiC power semiconductor device after removing the upper temporary substrate (130).

Next, referring to FIG. 2, another embodiment of the present invention includes a seed substrate preparation step (S1100), a device region formation step (S1200), a seed substrate reforming step (S1400), an upper temporary substrate bonding step (S1450), a seed region separation step (S1500), and a lower temporary substrate bonding step (S1600).

Meanwhile, the first fab process step (S1300) is performed in a state where the upper temporary substrate (130) is removed (S1451) and the bonding of the lower temporary substrate (150) is maintained, and the second fab process step (S1550) is performed after the lower temporary substrate (150) is removed (S1601).

This embodiment is different from the previously described embodiment in that the first and second fab process steps (S1300, S1550) are performed after the seed substrate reforming and seed region separation are completed.

The specific execution process of each step (S1100, S1200, S1400, S1450, S1500, S1600, S1451, S1601, S1300, S1550) is the same as the execution process of the corresponding step of the previously described embodiment. Therefore, the previous description is replaced.

Next, with reference to FIGS. 3 and 4, the first and second fab process steps according to the type of SiC power semiconductor device will be specifically described.

FIG. 3 (A) is a case where the SiC power semiconductor device is a Planar MOSFET.

Referring to FIG. 3 (A), the first fab process step (S300, S1300) includes a doping step of forming an ion implantation doping region (210) for a source contact on the upper side of the device region (140), and an upper electrode forming step of forming a gate electrode (230) and a source electrode (220) on the upper surface of the device region (140).

The second fab process step (S550, S1550) deposits a drain electrode (240) on the lower surface of the seed region (20), and performs heat treatment for ohmic contact.

The heat treatment can be performed while the lower temporary substrate (150) is bonded.

FIG. 3 (B) is a case where the SiC power semiconductor device is a trench MOSFET.

Referring to FIG. 3 (B), the first fab process step (S300, S1300) includes a doping step for forming an ion implantation doping region (210) for a source contact on the upper side of the device region (140), a gate trench forming step for forming a trench in which a gate electrode (230) will be formed, and an upper electrode forming step for forming a gate electrode (230) and a source electrode (220) on the upper surface of the device region (140).

The second fab process step (S550, S1550) deposits a drain electrode (240) on the lower surface of the seed region (20), and performs heat treatment for an ohmic contact.

Heat treatment can be performed while the lower temporary substrate (150) is bonded.

FIG. 4 (A) is a case where the SiC power semiconductor element is a Schottky diode.

Referring to FIG. 4 (A), the first fab process step (S300, S1300) includes an upper electrode forming step of forming an anode electrode (310) formed as a Schottky contact on the upper surface of the element region (140).

The second fab process step (S550, S1550) deposits a metal electrode (320) on the lower surface of the seed region (20), and performs heat treatment for ohmic contact.

FIG. 4 (B) is a case where the SiC power semiconductor device is a trench P-N junction diode.

Referring to FIG. 4 (B), the first fab process step (S300, S1300) includes a trench formation step of forming a plurality of trenches (330) on the upper surface of the device region (140), a P-doping step of performing P-doping on the inner side (331) of the trenches, and an upper electrode formation step of forming an anode electrode (310) formed as a Schottkey contact on the upper surface of the device region (140) and the inner side of the trenches.

The second fab process step (S550, S1550) deposits a metal electrode (320) on the lower surface of the seed region (20), and performs heat treatment for an ohmic contact.

What is claimed is:

1. Method for manufacturing a SiC power semiconductor device through a hot self-split process, comprising:
a seed substrate preparation step of preparing a SiC seed substrate having conductivity;
device region forming step of forming device region including a SiC drift layer epitaxially grown on the SiC seed substrate;
a first fab process step including a doping process and an electrode forming process for forming one of a planar MOSFET, a trench MOSFET, a Schottky diode, and a trench P-N junction diode on the device region;
a seed substrate reforming step of irradiating a stealth laser inside the SiC seed substrate to form a reforming layer parallel to the growth plane of the SiC seed substrate over the entire inside of the SiC seed substrate;
an upper temporary substrate bonding step of bonding an upper temporary substrate to an upper surface of the device region via an upper bonding layer;
a seed region separation step in which the SiC seed substrate is separated with the reforming layer as the boundary to form a seed region;
a second fab process step in which an electrode is formed on the lower surface of the seed region; and
a lower temporary substrate bonding step in which a lower temporary substrate is bonded to the lower surface of the seed region via a lower bonding layer; and
wherein the seed region separation step is performed without an external force by thermal/mechanical stress due to a difference in thermal expansion rate and thickness on both sides with the reforming layer as the boundary.

2. The method of claim 1, wherein the seed region separation step is performed in a process of cooling from a bonding temperature for bonding the upper temporary substrate.

3. The method of claim 2, wherein further comprises an upper temporary substrate removal step of removing the upper temporary substrate after performing the lower temporary substrate bonding step; and a lower temporary substrate removal step of removing the lower temporary substrate after removing the upper temporary substrate.

4. The method of claim 3, wherein the first fab process step is performed while removing the upper temporary substrate and maintaining bonding of the lower temporary substrate, and the second fab process step is performed after removing the lower temporary substrate.

5. The method of claim 1, wherein the first fab process step comprises a doping step of forming a doping region for a source contact on an upper side of the device region; and an upper electrode formation step of forming a gate electrode and the source contact on an upper surface of the device region; thereby forming the Planar MOSFET in the device region.

6. The method of claim 1, wherein the first fab process step comprises a doping step of forming a doping region for a source contact on an upper side of the device region; a gate trench forming step of forming a trench in which a gate electrode is to be formed; and an upper electrode forming step of forming the gate electrode and the source contact on an upper surface of the device region, thereby forming the trench MOSFET in the device region.

7. The method of claim 1, wherein the first fab process step comprises an upper electrode forming step of forming an anode electrode formed as a Schottky contact on an upper surface of the device region, thereby forming the Schottky diode in the device region.

8. The method of claim 1, wherein the first fab process step comprises a trench forming step of forming a plurality of trenches on an upper surface of the device region; a P-doping step of performing P-doping on the inside of the trenches; and an upper electrode forming step of forming an anode electrode formed as a Schottkey contact on the upper surface of the device region and the inner surface of the trenches, thereby forming the trench P-N junction diode in the device region.

9. The method of claim 3, wherein the second fab process step deposits a drain electrode to form the Planar MOSFET or the Trench MOSFET, or deposits a metal electrode to form the Schottky diode or the Trench P-N J unction diode, and after bonding the lower temporary substrate, heat treatment is performed for ohmic contact of the drain electrode or the metal electrode.

10. The method of claim 1, wherein the SiC seed substrate is repeatedly provided as a SiC seed substrate for the growth of the SiC drift layer after the seed region is separated.
